(19) United States
(12) Patent Application Publication
(10) Pub. No.: US 2026/0342633 A1
(43) Pub. Date: Oct. 29, 2026

(54) FOURIER TRANSFORMATION TECHNIQUE

(71) Applicant: Telefonaktiebolaget LM Ericsson (publ), Stockholm (SE)

(72) Inventors: András RÁCZ, Budapest (HU); András VERES, Budapest (HU); Péter HÁGA, Budapest (HU); Tamas BORSOS, Budapest (HU); Zsolt KENESI, Budapest (HU)

(21) Appl. No.: 18/879,483

(22) PCT Filed: Jun. 30, 2023
(86) PCT No.: PCT/EP2023/068056

§ 371 Date: Dec. 27, 2024

Related U.S. Application Data
(60) Provisional application No. 63/357,135, filed on Jun. 30, 2022.

(51) Int. Cl. H04L 27/26

(52) U.S. Cl. CPC H04L 27/2628

(57) ABSTRACT

A device for generating a time domain signal based on binary-valued frequency domain components is described. The device includes input neurons representing binary values of the binary-valued frequency domain components; neuromorphic couplings configured to map the binary-valued frequency domain components to time domain components of the time domain signal using weights according to an inverse discrete Fourier transformation, IDFT; and output neurons representing the time domain components of the time domain signal, wherein each of the output neurons is configured to sum up contributions mapped to the respective one of the output neurons by the neuromorphic couplings from each of the input neurons.

### TECHNICAL FIELD

The present disclosure relates to a technique for performing a Fourier transformation. More specifically, and without limitation, a device and a method are provided for generating a time domain signal for orthogonal frequency division multiplexing.

### BACKGROUND

The Third Generation Partnership Project (3GPP) defines multiple radio access technologies (RATs) including fourth generation (4G) Long Term Evolution (LTE) and fifth generation (5G). Furthermore, IEEE and the Wi-Fi Alliance define RATs also referred to as Wi-Fi. Such RATs enable radio communications in downlinks (DLs) from a radio access network (RAN) comprising base stations to radio devices, in uplinks (ULs) from radio devices to the RAN, and in sidelinks (SLs) from radio device to radio device—also referred to as device-to-device (D2D) communication—without going through a base station. Radio devices for 3GPP RATs and Wi-Fi are also referred to as user equipments (UEs) and mobile stations (MSs), respectively. Herein, base stations and radio devices are collectively referred to as stations. Such RATs use orthogonal frequency division multiplexing (OFDM) and demultiplexing for transmitting to and receiving from one or more stations, including orthogonal frequency division multiple access (OFDMA).

Energy efficiency of stations, such as devices for the internet of things (IoT devices), is critical as the number of stations increases. Neuromorphic computing is a computation paradigm that has the potential to overcome some bottlenecks of the classical von-Neumann architecture. Such benefits include low-energy, event-driven computation, as well as parallelism and co-location of memory and computation. Event-driven computation means that a computation takes place only for active input, which reduces energy consumption. This can be an important advantage, for example, in low-power or so-called zero-power IoT devices, including simple sensory devices. Zero-power may mean that the IoT device relies on harvesting energy from its environment or is powered by usage, e.g., the mechanical energy of pressing a light switch.

Hardware devices for neuromorphic computation are currently advancing, including neuromorphic chips in research such as the “Intel Loihi”, and entering commercial availability.

The document US 2021/0326689 A1 proposes a way to set conductance values in an analogue circuit for executing matrix dot product operation, such that negative and positive values in the matrix can be allowed. The resulting dot-product is the voltage value on different output lines. The voltage values are further converted to binary 0 or 1 and are used to make classification decisions, e.g., for classifying an image. The primary use case shown is image processing.

The document U.S. Pat. No. 10,664,271 B2 describes a resistive memory circuit used to execute a dot-product operation, wherein an analogue circuit executes the computation and the result is represented as by the value of an analogue signal on the output. Analogue to digital conversion is applied on the analogue signal.

The document US 2020/0356847 A1 describes a programmable conductor circuit used as a sequence of input spikes. A rate of spikes represents an input value. A sequence of spikes on the output represents the output value.

Existing analogue circuits for dot-product calculation, such as the technique of document US 2021/0326689 A1, assume that the input of the calculation are real-valued signals. As a consequence, the existing analogue circuits include components that handle the possible negative values in the calculations and assume that the input is represented by an analogue-valued signal, e.g. a voltage or a current. However, the existing technique is not optimal when the input signal is binary-valued and cannot be directly applied for spike-based digital input.

Other existing analogue circuits that are based on Ohm's law to execute the computation with analogue voltage and current (e.g., according to the document U.S. Pat. No. 10,664,271 B2 or document US 2021/0326689) require synchronous operation of the components representing the values to be combined, e.g. to feed the input synchronously and read out the result synchronously, which adds to complexity and limitations of use.

### SUMMARY

Accordingly, there is a need for a technique that energy-efficiently performs a discrete Fourier transformation (DFT). An alternative or more specific object is to provide a DFT technique, which input and/or output are spike-encoded digital data and can work asynchronously.

As to one device aspect, a device for generating a time domain signal based on binary-valued frequency domain components is provided. The device comprises input neurons for representing binary values of the binary-valued frequency domain components. The device further comprises neuromorphic couplings configured to map the binary-valued frequency domain components to time domain components of the time domain signal using weights according to an inverse discrete Fourier transformation (IDFT). The device further comprises output neurons for representing the time domain components of the time domain signal. Each of the output neurons is configured to sum up contributions mapped to the respective one of the output neurons by the neuromorphic couplings from each of the input neurons.

Embodiments of the device may generate the time domain components based on asynchronously received frequency domain components. Each of the input neurons may (e.g., time-integrate or buffer) at least one spike that represents a value of one for the respective one of the frequency domain components. For example, spikes may be received at different input neurons at different times (i.e., asynchronously) and still be processed to generate the contributions according to the mapping performed by the neuromorphic couplings and to generate the time domain components by the output neurons.

The neuromorphic couplings may perform a neuromorphic computation, e.g. a matrix product between the input neurons (e.g., the values of the inner potentials of the input neurons) as an input vector and the weights being elements of an IDFT matrix (i.e., a matrix for an Inverse Discrete Fourier Transform), or a plurality of scalar products (also referred to as dot-products) between the input neurons as the input vector and a row of the weights (i.e., the weights used for mapping to one of the time domain components). Optionally, the input vector may be encoded using a Vector Symbolic Architecture (VSA).

The input neurons (e.g., the values of the inner potentials of the input neurons) may represent the frequency domain components, i.e., the signal values at the different sub-carriers in the frequency domain (which may also be referred to as Fourier coefficients) for a given OFDM symbol.

The (e.g., complex-valued or real-valued) weights according to the inverse discrete Fourier transformation (IDFT) may be matrix coefficients of a unitary matrix of the IDFT, which may also be referred to as IDFT coefficients. As each product between the frequency components (of the input neurons) and the complex-valued weights of the unitary IDFT matrix can be decomposed into real and imaginary parts for the time domain components, the weights used for the mapping (by the neuromorphic couplings) of the frequency domain components (represented by the input neurons) to the time domain components (represented by the output neurons) may be real-valued.

If the mapping (by the neuromorphic couplings) is implemented according to a Fast Fourier Transformation (FFT) of the IDFT, the weights used by the neuromorphic couplings may also be referred to as FFT coefficients (which is not to be confused with the Fourier coefficients representing the frequency components).

The time domain signal resulting from the IDFT may be an orthogonal frequency division multiplexing (OFDM) signal. The OFDM signal may comprise an OFDM symbol. The output neurons (e.g., the values of the inner potentials of the output neurons) may represent the time domain components, i.e., the signal values (or samples) at the different points in time (e.g., within the duration of the respective OFDM symbol).

At least some embodiments of the device may perform an inverse DFT (e.g., a fast Fourier transform, FFT) with reduced energy consumption by virtue of the neuromorphic hardware (i.e., the input neurons, the neuromorphic couplings, and/or the output neurons), e.g., for an energy-efficient OFDM transceiver.

The input neurons, the neuromorphic coupling, and the output neurons may be implemented by (e.g., a single piece of) neuromorphic hardware. Alternatively or in addition, the neuromorphic couplings may correspond to a single intermediate layer between the input neurons and the output neurons. Alternatively or in addition, the neuromorphic couplings may correspond to synapses of the output neurons.

Alternatively or in addition, at least one or each of the input neurons may be a spiking neuron. Alternatively or in addition, at least one or each of the input neurons and/or at least one or each of the output neurons may be distinguished from neurons in regular artificial neural networks.

Each of the frequency domain components may be represented by a different one, or a different pair, of the input neurons. Alternatively or in addition, each of the time domain components may be represented by a different pair of the output neurons. The number of input neurons may be equal to the number of output neurons.

The device aspect may further comprise at least one of the following embodiments.

In an embodiment, the neuromorphic couplings may comprise resistances corresponding to the weights. The contributions may correspond to voltage drops at the resistances when currents corresponding to the binary-valued frequency domain components energize a respective one of the resistances.

Using the weights may correspond to multiplications of a respective one of the binary-valued frequency domain components with a respective one of the weights. The contributions may be the result of the multiplications.

Alternatively or in addition, the neuromorphic couplings may implement the multiplications (e.g., each of the multiplications) according to Ohm's law. For example, at least one of: the respective one of the binary-valued frequency domain components may be represented by a current, the respective one of the weights may be represented by a resistance, and the respective one of the contributions may correspond to the voltage drop at the resistance.

In an embodiment, a spike input at any one of the input neurons may correspond to a value of one of the respective one of the binary-valued frequency domain components. Alternatively or in addition, the absence of a spike input at any one of the input neurons within a predefined time window may correspond to a value of zero of the respective one of the binary-valued frequency domain components.

Optionally, the input neurons may or may not comprise or apply a non-linear function or a threshold to the binary-valued frequency domain components. Alternatively or in addition, the neuromorphic couplings and/or the output neurons may or may not comprise or apply a non-linear function or a threshold to the contributions.

In an embodiment, the neuromorphic couplings may be configured to energize a respective one of the weights for the mapping only when the binary-valued frequency domain component, which is mapped using the respective one of the weights, comprises a value of one. Alternatively or in addition, the neuromorphic couplings may be configured to not energize a respective one of the weights for the mapping when the binary-valued frequency domain component, which is mapped using the respective one of the weights, comprises a value of zero.

For example, the respective one of the weights may be energized by energy of the binary-valued frequency domain component representing the value of one.

An input signal and an output signal comprising a spike signal may also be referred to as a spike-based input and a spike-based output, respectively.

In an embodiment, at least one or each of the output neurons may comprise a spiking threshold. The spiking threshold of the respective one of the output neurons may be greater than the highest possible inner potential of the respective one of the output neurons that is reachable by activations on the input neurons.

The spiking threshold may be set such that the inner potential of the output neurons does not reach the spiking threshold of the output neurons. This may enable that the time domain components are linearly depending (e.g., proportional to) the frequency domain components.

In an embodiment, the input neurons may be configured to receive a spike signal. For example, the spike signal may represent application data encoded into spike activations.

In one variant, the input neurons receive the application data in the form of spikes (i.e., as a spike signal). The spike signal may result from encoding input data according to a neuromorphic representation. The neuromorphic representation, e.g., how the application data is encoded into spikes, may depend on the implementation. The input neurons may realize the representation via their spiking activities. In another variant, the input neurons may receive the application data as an analogue signal, e.g. a voltage may represent the real and imaginary parts of the frequency components.

The spike signal may be a spike-encoded signal. Alternatively or in addition, the input neurons may apply a time-dependent analysis of the spike signal resulting in the binary-valued frequency domain component represented by an electric potential (or voltage, e.g., a membrane potential or membrane voltage) of the input neuron.

At least one or each of the input neurons may comprise a reactance for integrating the respective spike signal over time. Alternatively or in addition, at least one or each of the input neurons may comprise a capacitance and a resistance defining a time scale for integrating the respective spike signal.

In an embodiment, at least one or each of the output neurons may comprise an electric potential representing a respective one of the time domain components. Alternatively or in addition, at least one or each of the output neurons may be configured to aggregate spike signals in the contributions resulting from the neuromorphic couplings mapping spike signals in the binary-valued frequency domain components from the input neurons.

The electric potential may be a voltage, e.g., a membrane potential or membrane voltage of the respective output neuron.

The aggregating (by the respective one of the output neurons) may comprise an adding (e.g., the afore-mentioned time integration) of the weighted spike signals from the input neurons. Alternatively or in addition, the electric potential may decay according to a resistance (e.g., a membrane resistance) and/or an equilibrium potential of the respective one of the output neurons.

In an embodiment, the input neurons may comprise a first input set of input neurons and a second input set of input neurons that is disjoint from the first input set. The first input set may be mapped to the time domain components using the weights according to the IDFT. The second input set may be mapped to the time domain components using the weights according to the IDFT with inverted sign.

In an embodiment, the input neurons may comprise a first input set of input neurons and a second input set of input neurons that is disjoint from the first input set. The first input set may be mapped to the time domain components using the weights according to the IDFT. The second input set may be mapped to the time domain components using the weights according to the IDFT. Each of the output neurons may be configured to sum up contributions mapped to the respective one of the output neurons from the first input set. Moreover, each of the output neurons may be configured to subtract contributions mapped to the respective one of the output neurons from the second input set.

In an embodiment, corresponding pairs of input neurons in the first and second sets may represent a modulation symbol according to at least one of on-off-keying (OOK) and phase-shift keying (PSK).

Referring to corresponding frequency domain components out of the first input set and the second input set in pairs (c⁺ᵢ, c⁻ᵢ), wherein c⁺ᵢ is the i-th frequency domain component out of the first input set and c; is the i-th frequency domain component out of the second input set, the pair of binary values (0,0) may represent a zero frequency domain component, the pair of binary values (1,0) may represent a plus one frequency domain component, and the pair of binary values (0,1) may represent a minus one frequency domain component.

The binary values (1,1) may be unused or equivalent to (0,0).

In an embodiment, the input neurons may comprise mutually disjoint first, second, third, and fourth input sets of input neurons. The first input set may be mapped to the time domain components using the weights according to the IDFT. The second input set may be mapped to the time domain components using the weights according to the IDFT with inverted sign. The third input set may be mapped to the time domain components using the weights according to the IDFT with a phase shift by +90 degrees. The fourth input set may be mapped to the time domain components using the weights according to the IDFT with a phase shift by −90 degrees.

Optionally in the embodiment, corresponding groups of input neurons in the first, second, third, and fourth sets may represent a modulation symbol according to at least one of Quadrature Phase-Shift Keying (QPSK) and Quadrature Amplitude Modulation (QAM) 4.

Referring to corresponding frequency domain components out of the first input set, the second input set, the third input set, and the fourth input set in groups (c⁽⁺⁾ᵢ, c⁽⁺⁾ᵢ, c^{(j)}ᵢ, c^{(-j)}ᵢ), the group of binary values (1,0,0,0) may represent a first QPSK constellation, the group of binary values (0,1,0,0) may represent a second QPSK constellation, the group of binary values (0,0,1,0) may represent a third QPSK constellation, and the group of binary values (0,0,0,1) may represent a fourth QPSK constellation.

In an embodiment, the output neurons may comprise a first output set of output neurons and a second output set of output neurons that is disjoint from the first output set. The neuromorphic couplings may be configured to map the binary-valued frequency domain components to the first output set using weights according to the real part of the IDFT. The neuromorphic couplings may be configured to further map the binary-valued frequency domain components to the second output set using weights according to the imaginary part of the IDFT.

In an embodiment, the input neurons may comprise an odd input set of N input neurons corresponding to odd frequency domain components and an even input set of N input neurons corresponding to even frequency domain components. Each of the odd input set and the even input set may be mapped to the time domain components using the weights according to the IDFT of size N. The neuromorphic couplings or the output neurons may be configured to sum up the contributions mapped to the respective one of the output neurons from the odd input set and the contributions mapped to the respective one of the output neurons from the even input set for the first N output neurons. The neuromorphic couplings or the output neurons may be configured to subtract the contributions mapped to the respective one of the output neurons from the even input set from the contributions mapped to the respective one of the output neurons from the odd input set for the second N output neurons.

The neuromorphic couplings splitting the input neurons corresponding to odd and even frequency domain components may enable a fast Fourier transformation (FFT) on neuromorphic hardware.

Alternatively or in addition, the contributions mapped to the respective one of the output neurons from the even input set may further comprise a phase factor. The phase factor may depend only on the respective one of the output neurons.

In an embodiment, at least one or each of the input neurons and/or at least one or each of the output neurons may comprise a reactance, optionally a capacitance or an inductance, for asynchronously collecting one or more spikes representing the binary value of the binary-valued frequency domain components.

For example, the input neurons may be emitting spikes such that they encode, e.g. for representing, input data (e.g., application data). Alternatively or in addition, the output neurons may collect the (e.g., asynchronously arriving) spikes resulting in the mapping of the frequency domain components to the time domain components by the neuromorphic couplings.

In an embodiment, the device may further comprise a demultiplexing unit. The demultiplexing unit may comprise a clock and a cyclic counter. The clock may be configured to cyclically increase the cyclic counter. The time domain components may be read out from the output neurons according to the cyclic counter.

The size of the cyclic counter (i.e., the number of different integer values representable by the cyclic counter) may correspond to the number of output neurons.

In an embodiment, the device may further comprise a radio frequency converter configured to up-converting a real part of a current one of the time domain components to a radio frequency and to up-converting an imaginary part of a current one of the time domain components to the radio frequency with a 90 degree phase shift.

According to another device aspect, a radio device for transmitting an orthogonal frequency division multiplexing symbol (OFDM symbol) is provided. The radio device comprises a radio interface for transmitting a time domain signal comprising the OFDM symbol. The radio device further comprises a device for neuromorphic computation according the one device aspect (e.g., any one of the embodiments of the one device aspect). The radio device further comprises a processing circuitry coupled to memory that is configured to store instructions of a radio communications protocol. The processing circuitry is operable to execute the instructions, such that the processing circuitry provides the binary-valued frequency domain components to the input neurons of the device. The output neurons of the device may be coupled to the radio interface to provide the time domain signal comprising the OFDM symbol.

According to still another device aspect, a user equipment (UE) configured to communicate with a base station on an uplink (UL) or with another radio device on a sidelink (SL) is provided. The UE comprises a radio interface for transmitting an OFDM symbol. The UE further comprises a device for neuromorphic computation according the one device aspect (e.g., any one of the embodiments of the one device aspect). The UE further comprises a processing circuitry coupled to memory that is configured to store instructions of a radio communications protocol. The processing circuitry may be operable to execute the instructions, such that the processing circuitry provides the binary-valued frequency domain components to the input neurons of the device. The output neurons of the device are coupled to the radio interface to provide the time domain signal comprising the OFDM symbol.

According to one method aspect, a method of generating a time domain signal based on binary-valued frequency domain components is provided. The method comprises a step of representing binary values of the binary-valued frequency domain components in input neurons. The method further comprises a step of mapping the binary-valued frequency domain components to time domain components of the time domain signal using weights according to an inverse discrete Fourier transformation (IDFT) in neuromorphic couplings. The method further comprises a step of representing the time domain components of the time domain signal in output neurons. Each of the output neurons may be configured to sum up contributions mapped to the respective one of the output neurons by the neuromorphic couplings from each of the input neurons.

The method according to the method aspect may further comprise any of the features or steps of any one of the embodiments of the one device aspect.

According to a further device aspect, a communication system is provided. The communication system includes a host computer comprising processing circuitry configure to provide user data. Alternatively or in addition, the host computer comprises a communication interface configured to forward user data to a (e.g., cellular and/or ad hoc) radio network for transmission to a user equipment (UE) and/or to receive user data through the radio network from the UE.

The UE may be an embodiment of the still other device aspect. Alternatively or in addition, the UE may comprise a radio interface and processing circuitry. The processing circuitry of the UE may be configured to provide the binary-valued frequency domain components (e.g., encoding the user data) to a device embodying the one device aspect (e.g., any one of the embodiments of the one device aspect).

The communication system may be embodied according to at least one of the following embodiments.

In an embodiment, the communication system may comprise the UE.

In an embodiment, the radio network may further comprise a base station, or a radio device functioning as a gateway, which is configured to communicate with the UE.

In an embodiment, the processing circuitry of the host computer may be configured to execute a host application, thereby providing the user data. Alternatively or in addition, the processing circuitry of the UE may be configured to execute a client application associated with the host application.

In any aspect, the circuit architecture of at least some embodiments does not require a purpose-built analogue circuit. Embodiments can be directly applicable for implementation on general purpose neuromorphic hardware. For example, the technique may enable applying neuromorphic hardware in radio communication, which is an increasingly important area with only few existing solutions available so far.

The technique enables an energy-efficient implementation of the Discrete Fourier Transform (DFT) on general purpose neuromorphic hardware.

Alternatively or in addition, the input neurons and/or the output neuron may be implemented according to a Leaky Integrate and Fire (LIF) neurons to compute the IDFT for an input signal represented by neural spike activations as the binary-valued frequency domain components.

While referring to IDFT, the technique is readily applicable to a DFT and/or for generating frequency domain components based on time domain components (e.g., for receiving and/or demultiplexing an OFDM symbol).

The device may be embodied by a radio device. Without limitation, for example in a 3GPP implementation, any “radio device” may be a user equipment (UE).

The technique may be applied for generating an OFDM symbol, e.g. according to Third Generation Partnership Project (3GPP) New Radio (NR) or 3GPP Long Term Evolution (LTE) or according to the standard family IEEE 802.11 (Wi-Fi). In any radio access technology (RAT), the technique may be implemented for uplink (UL) or sidelink (SL) radio transmission. The SL may be implemented using proximity services (ProSe), e.g. according to a 3GPP specification.

Any radio device may be a user equipment (UE), e.g., according to a 3GPP specification. The time domain signal may be transmitted to a radio access network (RAN). The RAN may comprise one or more base stations. Alternatively or in addition, the radio device may be a node in a radio network, e.g. a vehicular, ad hoc and/or mesh network comprising two or more radio devices (e.g., vehicles such as cars), e.g., acting as remote radio device and/or relay radio device.

Any of the radio devices may be a 3GPP user equipment (UE) or a Wi-Fi station (STA). The radio device may be a mobile or portable station, a device for machine-type communication (MTC), a device for narrowband Internet of Things (NB-IoT) or a combination thereof. Examples for the UE and the mobile station include a mobile phone, a tablet computer and a self-driving vehicle. Examples for the portable station include a laptop computer and a television set. Examples for the MTC device or the NB-IoT device include robots, sensors and/or actuators, e.g., in manufacturing, automotive communication and home automation. The MTC device or the NB-IoT device may be implemented in a manufacturing plant, household appliances and consumer electronics.

Whenever referring to the RAN, the RAN may be implemented by one or more base stations (e.g., network nodes).

The radio device may be wirelessly connected or connectable (e.g., according to a radio resource control, RRC, state or active mode) with another radio device (e.g., the relay radio device) and/or at least one base station of the RAN.

The base station may encompass any station that is configured to provide radio access to any of the radio devices. The base stations may also be referred to as cell, transmission and reception point (TRP), radio access node or access point (AP). The base station and/or the relay radio device may provide a data link to a host computer providing the user data to the remote radio device or gathering user data from the remote radio device. Examples for the network node (e.g., base station) may include a 3G base station or Node B (NB), 4G base station or eNodeB (eNB), a 5G base station or gNodeB (gNB), a Wi-Fi AP, and a network controller (e.g., according to Bluetooth, ZigBee or Z-Wave).

The RAN may be implemented according to the Global System for Mobile Communications (GSM), the Universal Mobile Telecommunications System (UMTS), 3GPP Long Term Evolution (LTE) and/or 3GPP New Radio (NR).

Any aspect of the technique may be implemented on a Physical Layer (PHY), a Medium Access Control (MAC) layer, a Radio Link Control (RLC) layer, a packet data convergence protocol (PDCP) layer, and/or a Radio Resource Control (RRC) layer of a protocol stack for the radio communication.

Herein, referring to a protocol of a layer may also refer to the corresponding layer in the protocol stack. Vice versa, referring to a layer of the protocol stack may also refer to the corresponding protocol of the layer. Any protocol may be implemented by a corresponding method.

The device (e.g., the radio device) may further comprises processing circuitry (e.g., at least one processor) and a memory. Said memory comprises instructions executable by said at least one processor whereby the device is operative to perform a communications protocol for providing the frequency domain components, e.g., spike-encoded (i.e., as a spike-based signal).

As to a still further aspect, a communication system including a host computer is provided. The host computer comprises a processing circuitry configured to provide user data, e.g., triggering the time domain signal or in response to the time domain signal. The host computer further comprises a communication interface configured to forward the user data to a cellular network (e.g., through the RAN and/or the base station) for transmission to a UE (e.g., embodying the device aspect).

The UE comprises an embodiment of the device. Alternatively or in addition, the UE comprises a radio interface and processing circuitry, which is configured to execute a radio communication protocol for providing the frequency domain components to the device.

The communication system may further include the UE. Alternatively, or in addition, the cellular network may further include one or more base stations configured for radio communication with the UE and/or to provide a data link between the UE and the host computer using the method aspect.

Any one of the device, the radio device, the UE, the base station, the communication system or any node or station for embodying the technique may further include any feature disclosed in the context of the method aspect and/or the device aspect. Particularly, any one of the units and modules disclosed herein may be configured to perform or initiate one or more of the steps of the method aspect.

### BRIEF DESCRIPTION OF THE DRAWINGS

Further details of embodiments of the technique are described with reference to the enclosed drawings, wherein:

FIG. 1 shows a schematic block diagram of an embodiment of a device for generating a time domain signal based on binary-valued frequency domain components;

FIG. 2 shows a schematic block diagram of an embodiment of a device for generating a time domain signal based on binary-valued frequency domain components;

FIG. 3 schematically illustrates a more detailed embodiment of the device of FIG. 1;

FIG. 4 schematically illustrates a first example of the neuromorphic couplings, which may be implemented in any embodiment of the device of FIG. 1;

FIG. 5 schematically illustrates a second example of the neuromorphic couplings, which may be implemented in any embodiment of the device of FIG. 1;

FIG. 6 schematically illustrates a third example of the neuromorphic couplings, which may be implemented in any embodiment of the device of FIG. 1;

FIG. 7A schematically illustrates a first example of a spike-based signal, which may be implemented in any embodiment of the device of FIG. 1;

FIG. 7B schematically illustrates a second example of a spike-based signal, which may be implemented in any embodiment of the device of FIG. 1;

FIG. 7B schematically illustrates a second example of a spike-based signal, which may be implemented in any embodiment of the device of FIG. 1;

FIG. 8 schematically illustrates an example of a neuron, which may be implemented as input neurons and/or output neurons in any embodiment of the device of FIG. 1;

FIG. 9 schematically illustrates an example of a radio network including a radio device embodying the device of FIG. 1;

FIG. 10 shows a schematic block diagram of a radio device embodying the device of FIG. 1;

FIG. 11 schematically illustrates an example telecommunication network connected via an intermediate network to a host computer;

FIG. 12 shows a generalized block diagram of a host computer communicating via a base station or radio device functioning as a gateway with a user equipment over a partially wireless connection; and

FIGS. 13 and 14 show flowcharts for methods implemented in a communication system including a host computer, a base station or radio device functioning as a gateway and a user equipment.

### DETAILED DESCRIPTION

In the following description, for purposes of explanation and not limitation, specific details are set forth, such as a specific network environment in order to provide a thorough understanding of the technique disclosed herein. It will be apparent to one skilled in the art that the technique may be practiced in other embodiments that depart from these specific details. Moreover, while the following embodiments are primarily described for a New Radio (NR) or 5G implementation, it is readily apparent that the technique described herein may also be implemented for any other radio communication technique, including a Wireless Local Area Network (WLAN) implementation according to the standard family IEEE 802.11, 3GPP LTE (e.g., LTE-Advanced or a related radio access technique such as MulteFire), for Bluetooth according to the Bluetooth Special Interest Group (SIG), particularly Bluetooth Low Energy, Bluetooth Mesh Networking and Bluetooth broadcasting, for Z-Wave according to the Z-Wave Alliance or for ZigBee based on IEEE 802.15.4.

Moreover, those skilled in the art will appreciate that the functions, steps, units and modules explained herein may be implemented using neuromorphic hardware (e.g., neuromorphic chips). It will also be appreciated that, while the following embodiments are primarily described in context with methods and devices, the invention may also be embodied in a computer program product as well as in a system comprising at least one computer processor and memory coupled to the at least one processor, wherein the memory is encoded with one or more programs that may perform the functions and steps or implement the units and modules disclosed herein.

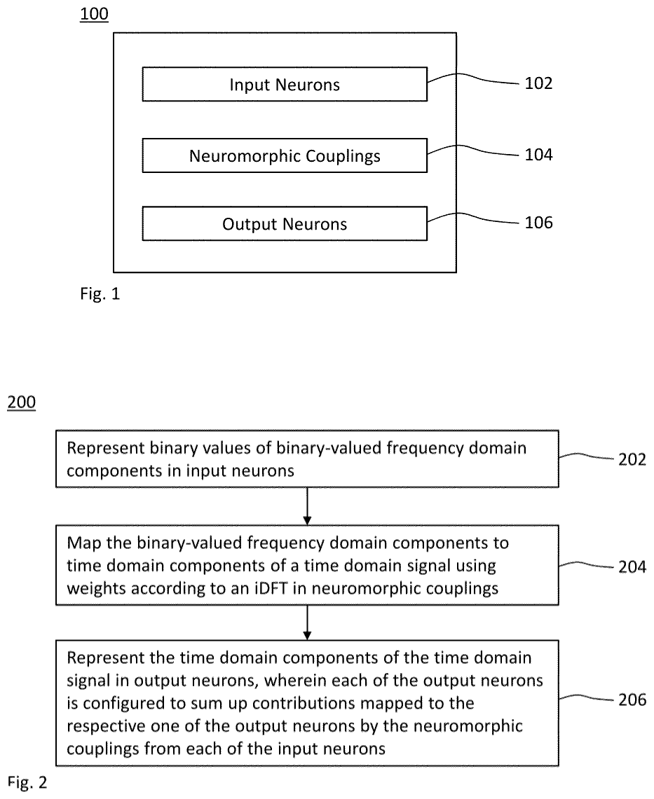

FIG. 1 schematically illustrates a block diagram of an embodiment of a device for generating a time domain signal based on binary-valued frequency domain components. The device is generically referred to by reference sign 100.

The device 100 comprises input neurons 102 representing binary values of the binary-valued frequency domain components. The device 100 further comprises neuromorphic couplings 104 configured to map the binary-valued frequency domain components to time domain components of the time domain signal using weights according to an inverse discrete Fourier transformation (IDFT). The device 100 further comprises output neurons 106 representing the time domain components of the time domain signal, wherein each of the output neurons 106 is configured to sum up contributions mapped to the respective one of the output neurons 106 by the neuromorphic couplings 104 from each of the input neurons 102.

Optionally, the device 100 comprises an up-converter for up-converting the time domain signal (e.g., a baseband signal) to a radio frequency for radio transmission.

Any of the features 102, 104, and 106 of the device 100 may be implemented by modules or units configured to provide the corresponding functionality using analog neuromorphic computing or digital neuromorphic computing. Herein, neuromorphic computing may refer to hardware that performs the computation (e.g., the multiplication by the weights or the summing up of the contributions) by a set of spiking neurons and the activations between them. Optionally, neuromorphic computing may refer to hardware that performs the computation in colocation with the memory storing the result of the computation (e.g., in-memory computation).

The device 100 may be embodied by any transmitting station (or briefly: transmitter). Alternatively or in addition, the device 100 may be embodied by a radio device, e.g., a user equipment (UE). The radio device may be configured for radio access to a radio access network (RAN) and/or for sidelink (SL) communication with another radio device.

The device 100 and the RAN or the other radio device may be in direct radio communication, e.g., at least for transmitting the time domain signal. The receiving station may be embodied by a base station (e.g., network node) of the RAN and/or the other radio device.

FIG. 2 shows an example flowchart for a method 200 of generating a time domain signal based on binary-valued frequency domain components.

In a step 202, binary values of the binary-valued frequency domain components are represented by means of input neurons. In a step 204, the binary-valued frequency domain components are mapped, by means of neuromorphic couplings, to time domain components of the time domain signal using weights according to an inverse discrete Fourier transformation (IDFT). In a step 206, the time domain components of the time domain signal are represented by means of output neurons. Each of the output neurons is configured to sum up contributions mapped to the respective one of the output neurons by the neuromorphic couplings (e.g., from each of the input neurons). The hardware is not required to execute a summation operation. For example, the summation may be implemented the respective neuron by integrating incoming spikes into its inner potential (also referred to as inner state). How integration is physically implemented may depend on the hardware realization of the respective neuron (e.g., analogue or digital).

Optionally, the method 200 further comprises a step of transmitting (e.g., data or control signaling) in one or more OFDM symbols, which are generated in the time domain signal according to the frequency domain components. For example, the frequency domain components may correspond to contiguous subcarriers. Each OFDM symbol may comprise a resource element on each subcarrier. Each resource element may carry a modulation symbol, e.g., according to quadrature amplitude modulation (QAM).

The method 200 may be performed by the device 100. For example, the modules 102, 104 and 106 (e.g., in a single piece of neuromorphic hardware) may perform the steps 202, 204 and 206, respectively.

The technique may be applied to a transmission on an uplink (UL), downlink (DL) or direct communications between radio devices, e.g., device-to-device (D2D) communications or sidelink (SL) communications.

Each of the transmitting station 100 and a corresponding receiving station may be a radio device or a base station.

Herein, any radio device 100 may be a mobile or portable station and/or any radio device wirelessly connectable to a base station or RAN, or to another radio device. For example, the radio device may be a user equipment (UE), a device for machine-type communication (MTC) or a device for (e.g., narrowband) Internet of Things (IoT). Two or more radio devices may be configured to wirelessly connect to each other, e.g., in an ad hoc radio network or via a 3GPP SL connection.

Furthermore, any base station may be a station providing radio access, may be part of a radio access network (RAN) and/or may be a node connected to the RAN for controlling the radio access. For example, the base station may be an access point, for example a Wi-Fi access point.

The technique may be embodied by a method 200 for mapping a spiking activity of the input neurons 102 (e.g., 0 meaning no event, 1 as spike event being indicative of a baseline, or optionally: two input neurons (indicative of 0 or +1 and 0 or −1, respectively) for each of real part and imaginary part of the frequency domain component.

Embodiments of the technique may provide an OFDM radio waveform as the time domain signal, e.g., wherein each of the output neuron 106 in a population is mapped to a distinct OFDM subcarrier and/or the spiking activity of that neuron is indicated by the modulation of that subcarrier. Optionally, the modulation scheme is less complex than QAM 64. The modulation may use OOK, PSK, and/or QPSK.

The time domain signal (e.g., the time domain OFDM signal) may be generated by executing the Inverse Fourier Transform with the output neurons 106 (e.g., an output neuron population). In other words, the neuromorphic couplings 104 may be part of the output neurons. Alternatively or in addition, every input neuron 102 may be connected to every output neuron 106 such that the weights (i.e., the connection weight matrix) corresponds to the Fourier coefficients.

In any embodiment, the output neurons 106 may comprise one output neuron population (i.e. a first output set) for the real part corresponding to the quadrature signal component and another set (i.e., a second output set) of output neurons corresponding to the imaginary part of the signal.

In any embodiment, the real and imaginary Fourier components of the DFT are applied as the weights (i.e., the connection weight matrix) for the real and imaginary neuron populations, respectively, i.e., for the first and second output set, respectively.

In any embodiment, a membrane potential of each output neuron (e.g., in the output population) may be configured to store an analogue value of the respective one of the time domain component, i.e., of the time domain signal at consecutive time samples. The output neuron may or may not be capable of generating a spike and/or may or may not comprise a spiking threshold for outputting a spike. In case the output neurons are capable of generating a spike and/or comprise a spiking threshold for outputting a spike, the spiking threshold may be set high enough such that the output neurons never spikes (e.g., at least during the neuromorphic computation of the IDFT). For example, the threshold is set higher than the largest possible value of the input sum. Preferably, the output neurons do not spike at any circumstances, otherwise the inner potential could incorrectly store the value resulting from the IDFT (i.e., the time domain component). In other words, the technique may be implemented by using the input neurons and/or output neurons in a very special way.

In any embodiment, the membrane potential of the output neurons may be read out in a circular fashion to obtain a time series of the resulting time domain signal (e.g., OFDM signal).

In any embodiment, a length of the time samples is set according to (e.g., predefined or configured) subcarrier spacing (SCS) and sampling frequency.

The time series complex-valued signal samples (i.e., the time domain components) may be used as the input to a quadrature modulator.

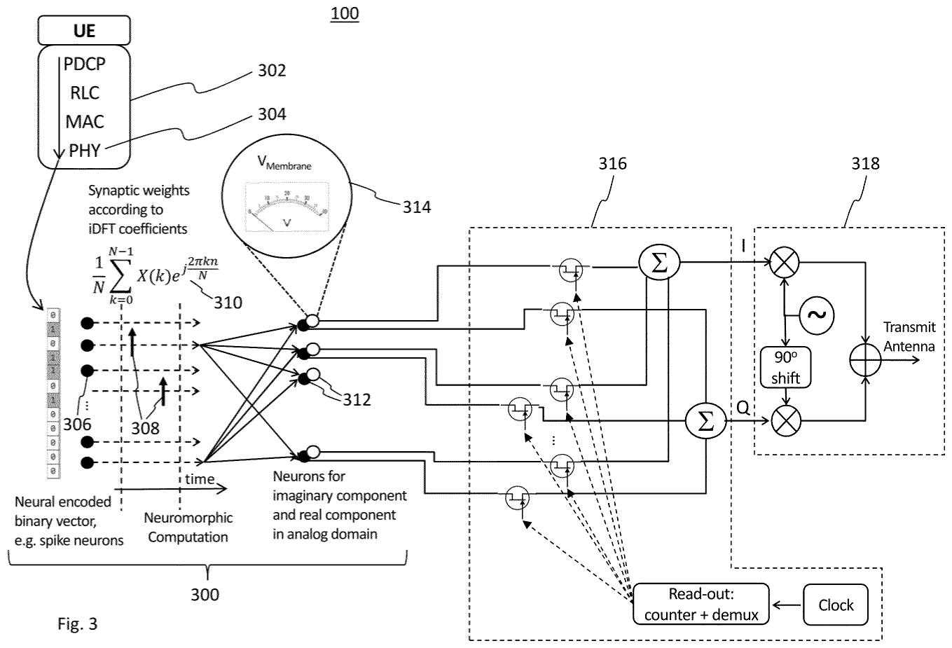

A detailed embodiment of the device 100 is illustrated in FIG. 3. A neuromorphic computation 300 of the inverse Discrete Fourier Transform (IDFT or an inverse DFT) is applied to generate OFDM radio waveform as the time domain signal or the receive the OFDM radio waveform for demodulating of the frequency components in the frequency domain.

### Input Data at the Input Neurons 306

The input data may result directly or indirectly from an application, and/or from a radio communication protocol stack 302, implemented at a radio device (e.g., UE) embodying the device 100. For example, an application layer at the top of the protocol stack may provide the data that is processed by the radio communication protocol stack 302. More specifically, a physical layer (PHY) 304 of the stack 302 may output the frequency domain components for the input neurons 306 (e.g., the input neurons 102).

The input data is assumed to be in the form of binary, typically high-dimensional vectors. These vectors are represented via the neural activity of a group of input neurons 306. In a variant, one layer of input neurons 306 is used, wherein there is one neuron corresponding to each vector dimension. Optionally, a spiking activity 308 of the input neuron 306 encodes a binary value of the respective vector dimension. This means that when the vector has a binary value of 1, the corresponding input neuron 306 emits a spike 308, otherwise the input neuron 306 remains silent.

The input neurons 306 do not have to be in synchronization, e.g., as long as a decay time of the membrane potential 314 of the input neurons 306 is longer than a time offset between the spikes 308. For rapid read-out, e.g. according to a symbol rate, the input neurons 306 and/or the output neurons 312 may be reset.

For example, a condition for including spikes in the same computation of the IDFT may be that a delay offset between the spikes of the input neurons 306 is less than a symbol time (e.g., a length of an OFDM symbol). That is, all input spikes should arrive at the input neurons 306 before the next read-out happens on the output neurons 312. The read-out may be performed done with periodicity of the symbol time.

As indicated also in the FIG. 3, the spikes representing the active vector dimensions do not necessarily have to happen synchronously. They may arrive asynchronously (e.g., within some time window) and this will not affect the resulting computation. This can be an important advantage and simplification in many applications, if strict time synchronization of the input neurons 308 can be omitted.

A data vector as the binary values of the frequency domain components may be not encoded, stored and/or processed as a vector of integers or Booleans as in a conventional compute architecture. In the neuromorphic computation 300 comprising the neuromorphic couplings, the spike patterns (at the input neurons 306 and/or the output neurons 312) may represent the information and there is no separate memory elements for storing the respective components. The information vector may be stored in pieces in the inner states (e.g., the membrane potentials 314) of the individual neurons 306 and/or 312.

In another variant, there can be two neurons encoding one vector dimension. In one example, two input neurons 306 may encode three possible values of 1, −1, 0, e.g., according to (1,0)=+1, (0,1)=−1, (0,0)=0. The weights 310 corresponding to the DFT may encode the minus sign for mapping the second one of each of the pairs of input neurons 306. When the first input neuron 306 of the respective pair fires, it corresponds to the value of 1, when the other second input neuron 306 of the pair fires, then it corresponds to the value of −1. When none of them fires then, it means a value of 0.

In another case there can be separate groups of input neurons 306 to represent a complexed-valued input vector. For example, one input neuron 306 may correspond to the binary value of the real part of the complex-valued frequency domain component. Another input neuron 306 may correspond to the binary value of the imaginary part of the respective one of the frequency domain components. Each of the real and imaginary parts of the respective one of the frequency domain components are binary. In a further case, each of the real and imaginary parts of the respective one of the frequency domain components may be represented by 2 neurons, which may allow to encode the values +1, −1, 0 for the respective part.

### Generating OFDM Waveform as the Time Domain Signal Via IDFT Computation 300

The dimensioned vector, e.g., the one binary value, or the two (i.e. pair of) binary values or the four (i.e., group of) binary values associated to one of the input neurons 306, is logically mapped to a frequency domain components (e.g., OFDM subcarriers), e.g., in a one-to-one manner (e.g., one pair or one group is reported to one subcarrier).

Alternatively or in addition, each of the input neurons 306 may be connected with one of the frequency domain components. The one or multiple input neurons 306 encoding the given vector dimension value is or are connected to output neurons 312 (e.g., a second neuron layer), optionally where the IDFT computation 300 is performed (i.e., the neuromorphic coupling 300 may be an input part of the output neurons 312). The weights 310 (e.g., a connection matrix) may include the IDFT coefficients, optionally modified with some additional terms that depend on the encoding applied on the input nodes (e.g., the input vector).

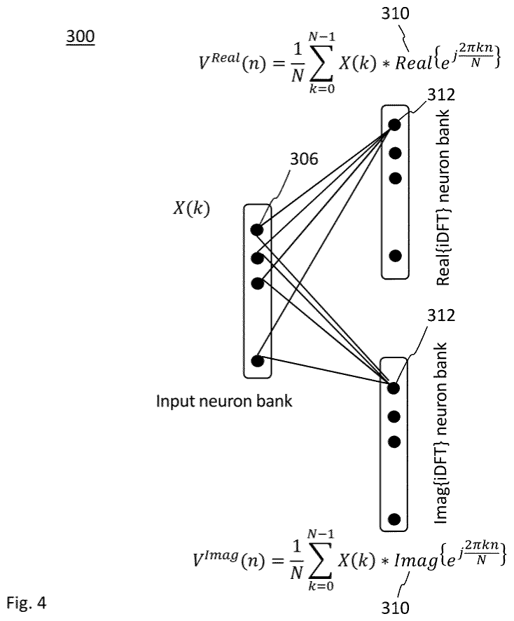

FIG. 4 schematically illustrates an example of the neuromorphic coupling 300 of an IDFT neuron bank 306, 312 (i.e., the input and output neurons) and connectivity weights 310 for a 1/0 encoded input, i.e. one binary input value is associated with one frequency domain component (e.g., one subcarrier).

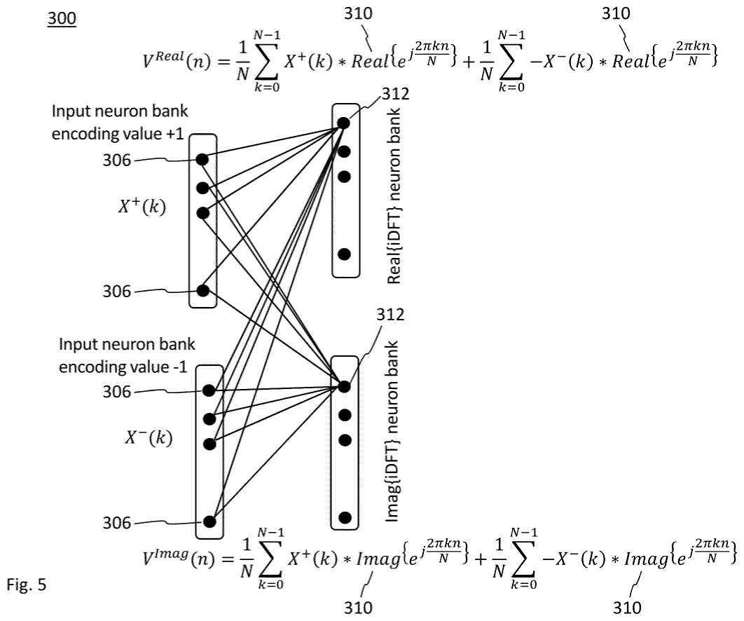

FIG. 5 schematically illustrates an example of the neuromorphic coupling 300 of an IDFT neuron bank 306, 312 (i.e., the input and output neurons) and connectivity weights 310 for +1/−1/0 encoded input, i.e. a pair of two binary input value being associated with one frequency domain component (e.g., one subcarrier).

In any embodiment, the neuromorphic coupling 300 may be composed of an input neuron bank with one (e.g., according to the embodiment of FIG. 4) or more (e.g., according to the embodiment of FIG. 5) input neurons 306 per frequency domain component (e.g., per vector dimension) and two output neuron banks (for a pair of output neurons 312) per time domain component. One output neuron 312 per time domain component is for the real part of the resulting IDFT computation. Another output neuron 312 per time domain component is for the imaginary value of the IDFT.

The connectivity weights 310 are according to the IDFT, i.e.,

$$Re \{ {e}^{j \frac{2 π k n}{N}} \} and Im \{ {e}^{j \frac{2 π k n}{N}} \} ,$$

wherein the index n corresponds to the n-th output neuron 312 on the output (i.e., in the time domain). That is, for the n-th output neuron 312 on the output, the weights 310 from the k-th input neuron 306 is according to the above expressions.

FIG. 3 further schematically illustrates applying the neuromorphic IDFT computation 300 in an OFDM transmitter. A memory of each of the neurons 306, 312 may correspond to an inner potential 314 (e.g., membrane potential), which is represented by voltage.

Advantageously, no digital to analog converter (DAC) is needed at the output neurons 312. The neuromorphic hardware 300, 306, 312 has a synergistic technical effect with the radio application.

The neuromorphic hardware 300, 306, 312 may be implemented in an analog domain and/or digital domain. The neuromorphic hardware 300, 306, 312 may achieve energy efficiency, because the neuromorphic computation is event-driven.

For 2 or 4, or more, (binary-valued) input neurons 306 per frequency domain component (e.g., encoding the input data vector), there are 2 or 4, or more, input neuron banks on the input and these input neuron banks are connected to the first and second output set of output neuron, i.e., the real and imaginary output banks, with weights from the IDFT modified with the value that the given input neuron corresponds to. For example, in case of +1/−1/0 input values, the input neurons 306 encoding the value of +1 are connected with the corresponding real and imaginary IDFT weights multiplied with +1, while the input neurons 306 encoding the value of −1 are connected with the IDFT weights multiplied with −1, e.g., as illustrated in FIG. 5.

The input connections can be constructed in a similar way in case the input vector is complexed valued and is represented by 2 or 4 neurons (depending on whether 0/+1 or +1/−0/0 are the possible values both for the “Real” and “Imag” components). The only difference as compared to the connectivity structure in FIG. 4 is that the input neuron banks for the “Real” and “Imag” components need to be connected only to the “Real” and “Imag” output neurons, respectively.

The computation happens by the input spikes summing up with the respective weighting in the membrane potential of the output neurons. We note that the spikes of the input neurons do not need to occur synchronously at once. The computation is not impacted if the input spikes arrive asynchronously. The inner potential 314 of output neuron n representing the real part of the IDFT value for time sample n is:

$${V}^{R e a l} ( n ) = \frac{1}{N} {\sum }_{k = 0}^{N - 1} X ( k ) * Real \{ {e}^{j \frac{2 π k n}{N}} \} ,$$

which is exactly the IDFT formula.

Similarly, the inner potential 314 of the n-th output neuron 312 representing the imaginary part of the IDFT value is:

$${V}^{Imag} ( n ) = \frac{1}{N} {\sum }_{k = 0}^{N - 1} X ( k ) * Imag \{ {e}^{j \frac{2 π k n}{N}} \} .$$

### Read-Out of the Neuron Inner Potentials

The next step in the execution in FIG. 3 is to read out the resulting IDFT output from the output neurons 312 and create an analogue valued time series signal, which can be directly used for carrier modulation, e.g., to make quadrature modulation in our case.

As explained in the previous step, the membrane potential 314 of the output neurons will store the resulting IDFT value. What remains is to access the inner state of the neurons and read out the membrane potential. It may depend on the particular neuron hardware realization how the access to the neuron inner state is provided but it is typically available in most of the neuron implementations.

In an embodiment, it is proposed to use a simple digital circuitry, composed of a digital counter plus demultiplexer, where the counter is stepped through the time step indices (i.e., corresponding to the output neurons) and the demultiplexer activates the respective output circuit, which drives a switching element (e.g., a MOSFET transistor), which switches the given neuron inner potential circuit to the output. With this mechanism at each time stamp the next neuron in the row is connected to the output.

The same switching mechanism may be applied for the first and second output set of output neurons 314 for the real and imaginary neurons in parallel, resulting in the complexed value components on the in-phase (I) and quadrature (Q) lines, respectively, which eventually may drive a quadrature modulator directly.

Any embodiment may use at least one of the following features of neuromorphic computing.

Neuromorphic hardware 300, e.g., Spiking Neural Networks (SNNs), may be designed to mimic the operation of biological neurons and their spike-based communication.

In SNNs, all the information carried between the neurons are represented by spikes. A spike itself can be considered as binary data, wherein the presence of a spike implicitly carries the information. An example for devices generating spike type of data are neuromorphic or event cameras, wherein each pixel directly feeds corresponding one or more neurons, and these neurons emit spikes when the change in light intensity exceeds a predefined threshold.

Other types of sensors, such as artificial cochlea, skin or touch sensors are directly generating spikes as output signal, or actuators, like robotic arms, which can be controlled via spike signals. There are also chips executing neuromorphic computing as opposed to traditional arithmetic compute, suitable to process e.g., the outputs of neuromorphic sensors.

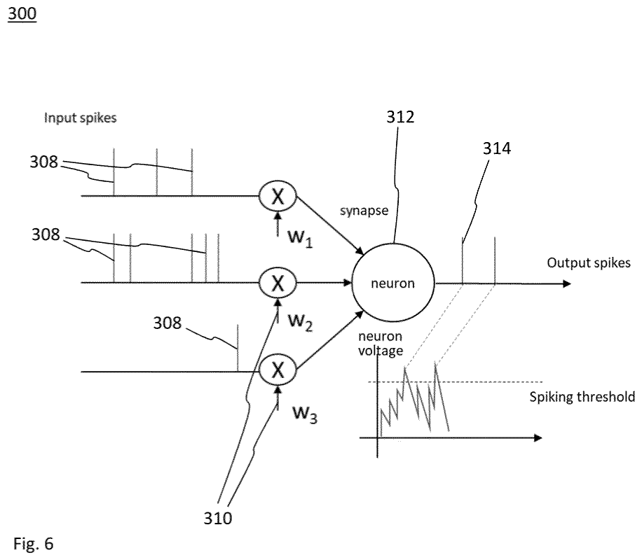

The basic operation of a neuron model is illustrated in FIG. 6. Each spike received on any of the input synapses of the neuron (weighted with the synapse weight) increase the voltage potential of the neuron and when it reaches a threshold, the neuron emits an output spike. It is also called as integrate and fire neuron model. An SNN is a collection of many hundreds or thousands of such neurons, which are inter-connected via synapses according to below model. The connections are not full mesh and are typically localized.

FIG. 6 schematically illustrates a neuron model 300 (i.e., a part of the neuromorphic hardware) including weights 310 for the mapping at an output neuron 312.

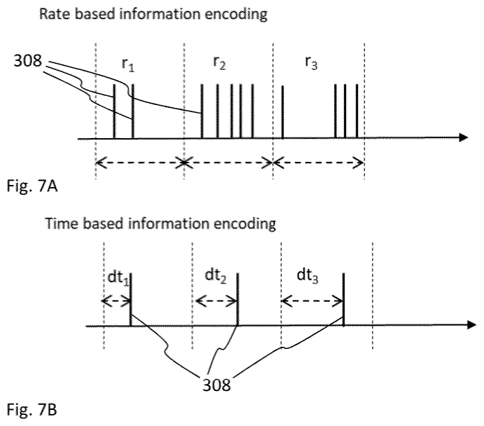

The information may be encoded into a rate of spikes or into a timing of individual spikes, e.g. as indicated in FIGS. 7A and 7B, respectively. For example, when the spike rate carries the information, then a higher spike rate might be the representation of a larger numerical number. In case of time based encoding, the relative time between spikes or in relation to some reference may carry information, e.g., a larger relative delay between spikes may indicate a larger encoded numerical value as compared to the first spike. When delay jitters occur, they can obviously distort the encoded value and can cause noise and inaccuracies in the neuromorphic system.

FIGS. 7A and 7B illustrate examples or a rate-based and time-based neural encoding.

Due to the nature of spike-based communication and its communication features, the above embodiments can fulfill special requirements for radio technology to effectively support distributed neuromorphic computation. In scenarios where spiking components are wirelessly communicating to each other, the radio technology needs to have the following capabilities: (i) low delay and low jitter to preserve the time sensitive aspect of spike information encoding; (ii) medium access and resource allocation methods must support unpredictable and/or burst-like traffic patterns; (iii) both unicast and groupcast communication will be needed to effectively support dense, local inter-neuron connectivity, as well as, sparse and remote synapses; (iv) usual loss and Block Error Rate (BLER) mitigation algorithms, like radio retransmission or large transmission buffer sizes may be applied only with significant limitations.

These unique properties altogether create a special situation regarding the communication requirements of spike data, which none of the existing access and resource sharing scheme can fulfill in an optimal way.

Any embodiment may implement at least one of the following neuromorphic hardware implementation options.

Embodiments of the neuromorphic IDFT computation 300 and the device 100 can be applied on any neuromorphic hardware. The hardware may be generally distinguished between analogue and digital neuromorphic hardware chips. Embodiments of the method 200 are not restricted to any of these. For illustration, some guidelines for the different implementation cases are summarized below.

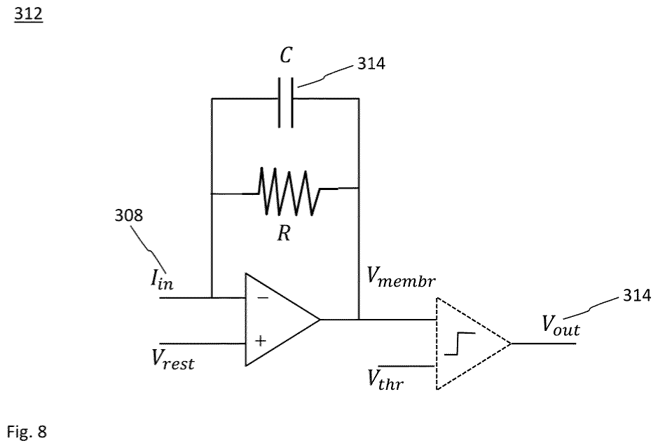

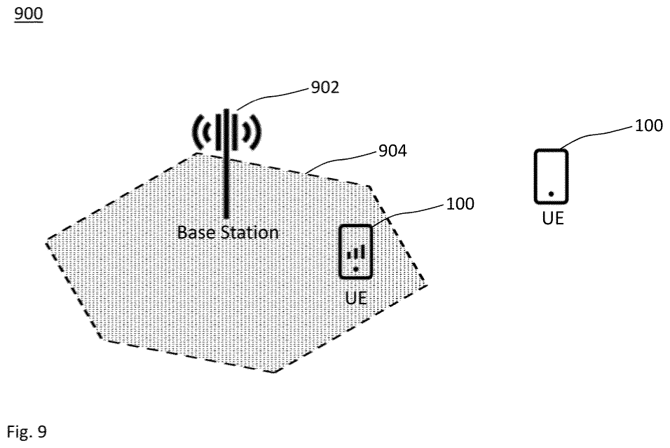

An analogue implementation of a neuromorphic chip can be as simple as a capacitor, a resistor and a comparator circuit, e.g. as schematically illustrated in FIG. 8. The input current, whose source can be a spike from an upstream neuron loads the capacitor 314. The capacitor has a constant leakage via the resistor. The voltage on the capacitor is the membrane potential of the neuron. For the IDFT computation case, the resulting value of the given IDFT component may be stored in the membrane potential 314 of the neuron 312. Optionally, the membrane potential 314 of the neuron 312 is fed into a comparator and when it reaches a threshold, a voltage spike is emitted on the output. Otherwise, the voltage 314 of the capacitor is directly at the output 314.

An analogue neuromorphic chip may be composed of thousands of such simple circuitry elements, which need to be connected with a programmable inter-connect circuitry. The weights 310 on the synaptic inter-connections may be set e.g., by selecting the resistor value on the inter-connections. The neuron circuit parameters, such as R, C or the voltage threshold, together with possibly other neuron parameters are programmable in a similar way.

FIG. 8 schematically illustrates a simple example on an implementation of an analogue neuron 312.

Other type of neuromorphic hardware elements may implement the neuron operations in a digital way. In this case the neuro chip may consists of so called neural cores, where each neural core implement a number of single neurons as simple elementary compute and memory element. The neuron computation is programmable with a largely reduced instruction set, which is the minimal instructions needed to compute the neuron state updates. The computation is triggered based on the input event, i.e., if no event is received no state update needs to be computed. Similarly, as to the previous case, there is need for a programmable inter-connect routing network between the cores. In the digital case, digital encoded, short mini-packets need to be routed on the on-chip network between the cores. The communication and neuron state updates may be done in a synchronous way, meaning that the state updates happen in sync at all neurons or it can be done in an asynchronous way.

Both the analogue and the digital neuron implementation exhibit the benefit of largely parallel computation, as state updates happen at each neuron in parallel, energy efficiency, meaning that computation is event based and no energy is consumed when there is no input event. For example, when the input data has a value of zero at some dimensions, there will be no spike events, consequently no computation will be performed for the zero components. This is in contrast to conventional matrix arithmetic where the same multiplication, summation is performed for the zero valued components as well, consuming the same energy independent of the value to be computed.

Another important benefit, equally available for analogue and digital variants is the co-location of memory and compute units. There is no separate CPU and memory in these architectures, consequently there is no need to shuffle data between CPU and memory, which is time and energy consuming and can quickly become the bottleneck of parallelization.

The device 100 may be embodied by radio devices, e.g., UEs, in a (e.g., cellular) radio access network 900 comprising base stations 902 (e.g., network nodes) each serving one or more cells 904. Alternatively or in addition, the device may be embodied by radio devices 100 in direct (e.g., sidelink) communication.

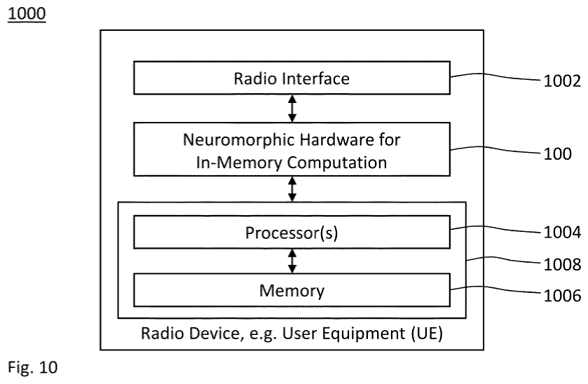

FIG. 10 shows a schematic block diagram for an embodiment of the device 100. The device 100 comprises neuromorphic hardware embodying the device 100 for performing the method 200.

As schematically illustrated in FIG. 10, the device 100 may be embodied by a radio device 1000, e.g., a transmitting UE (or, alternatively, by a base station, e.g., a gNodeB).

The radio device 1000 comprises a radio interface 1002 coupled to the device 100 for radio communication (e.g., radio transmission of the generated time domain signal) with one or more receiving stations, e.g., functioning as a receiving base station or a receiving UE.

The radio device 100 may or may not further comprise processing circuitry 1008, e.g., one or more processors 1004 and memory 1006 coupled to the processors 1004. For example, the memory 1006 may be encoded with instructions that implement radio communication protocols and/or for providing the binary-valued frequency domain components to the device 100.

In a variant, the radio device comprises no regular CPU and memory. The device 100 may comprise exclusively neuromorphic hardware. For example, the radio device 100 replaces regular protocol stacks (e.g., at least one of PDCP, RLC, and MAC) by neuromorphic hardware. In another variant, the device comprises at least one of an ASICS, FPGA, and a CPU for some auxiliary tasks.

The neuromorphic hardware embodying the device 100 may comprise a spiking neural network (SNN). In contrast, the processing circuitry 1008 may obey a von-Neumann architecture.

The one or more processors 1004 may be a combination of one or more of a microprocessor, controller, microcontroller, central processing unit, digital signal processor, application specific integrated circuit, field programmable gate array, or any other suitable computing device, resource, or combination of hardware, microcode and/or encoded logic operable to provide, either alone or in conjunction with other components of the radio device 1000, such as the memory 1006 and/or the neuromorphic hardware of the device 100, transmitter functionality. For example, the one or more processors 1004 may execute instructions stored in the memory 1006. Such functionality may include providing, or triggering, various features and steps discussed herein, including any of the benefits disclosed herein. The expression “the device being operative to perform an action” may denote the device 100 being configured to perform the action.

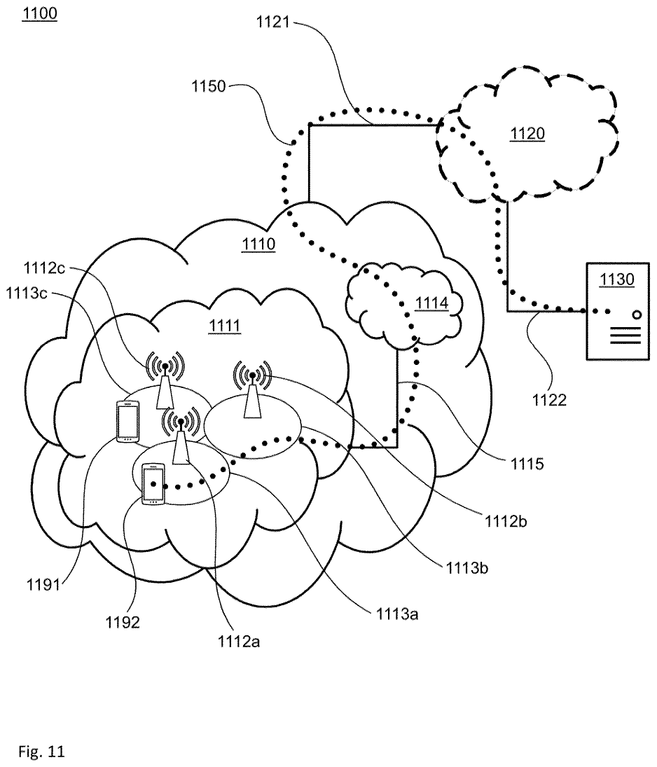

With reference to FIG. 11, in accordance with an embodiment, a communication system 1100 includes a telecommunication network 1110, such as a 3GPP-type cellular network, which comprises an access network 1111, such as a radio access network, and a core network 1114. The access network 1111 comprises a plurality of base stations 1112a, 1112b, 1112c, such as NBs, eNBs, gNBs or other types of wireless access points, each defining a corresponding coverage area 1113a, 1113b, 1113c. Each base station 1112a, 1112b, 1112c is connectable to the core network 1114 over a wired or wireless connection 1115. A first user equipment (UE) 1191 located in coverage area 1113c is configured to wirelessly connect to, or be paged by, the corresponding base station 1112c. A second UE 1192 in coverage area 1113a is wirelessly connectable to the corresponding base station 1112a. While a plurality of UEs 1191, 1192 are illustrated in this example, the disclosed embodiments are equally applicable to a situation where a sole UE is in the coverage area or where a sole UE is connecting to the corresponding base station 1112.

Any of the base stations 1112 and the UEs 1191, 1192 may embody the device 100.

The telecommunication network 1110 is itself connected to a host computer 1130, which may be embodied in the hardware and/or software of a standalone server, a cloud-implemented server, a distributed server or as processing resources in a server farm. The host computer 1130 may be under the ownership or control of a service provider, or may be operated by the service provider or on behalf of the service provider. The connections 1121, 1122 between the telecommunication network 1110 and the host computer 1130 may extend directly from the core network 1114 to the host computer 1130 or may go via an optional intermediate network 1120. The intermediate network 1120 may be one of, or a combination of more than one of, a public, private or hosted network; the intermediate network 1120, if any, may be a backbone network or the Internet; in particular, the intermediate network 1120 may comprise two or more sub-networks (not shown).

The communication system 1100 of FIG. 11 as a whole enables connectivity between one of the connected UEs 1191, 1192 and the host computer 1130. The connectivity may be described as an over-the-top (OTT) connection 1150. The host computer 1130 and the connected UEs 1191, 1192 are configured to communicate data and/or signaling via the OTT connection 1150, using the access network 1111, the core network 1114, any intermediate network 1120 and possible further infrastructure (not shown) as intermediaries. The OTT connection 1150 may be transparent in the sense that the participating communication devices through which the OTT connection 1150 passes are unaware of routing of uplink and downlink communications. For example, a base station 1112 need not be informed about the past routing of an incoming downlink communication with data originating from a host computer 1130 to be forwarded (e.g., handed over) to a connected UE 1191. Similarly, the base station 1112 need not be aware of the future routing of an outgoing uplink communication originating from the UE 1191 towards the host computer 1130.

By virtue of the method 200 being performed by any one of the UEs 1191 or 1192 and/or any one of the base stations 1112, the energy consumption and/or CO2 emissions of the OTT connection 1150 can be reduced.

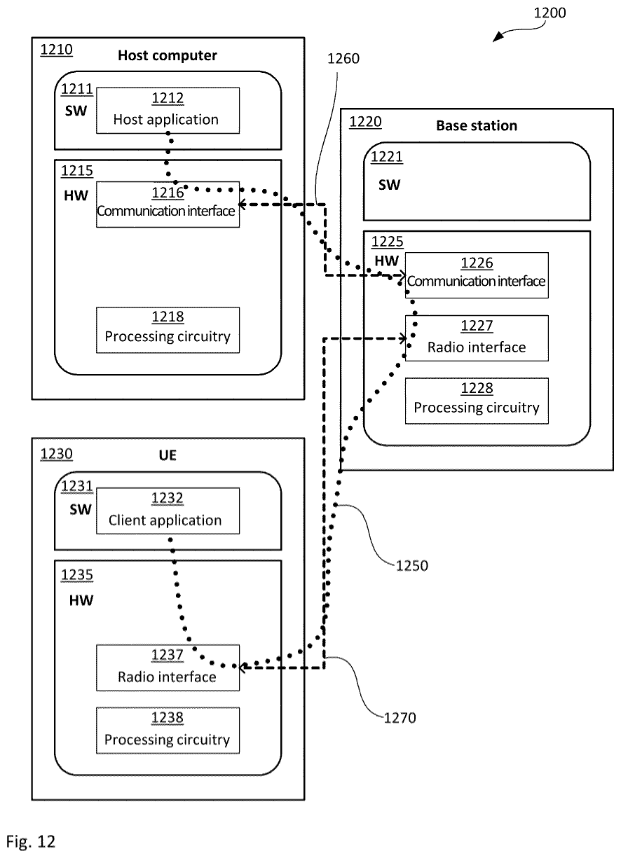

Example implementations, in accordance with an embodiment of the UE, base station and host computer discussed in the preceding paragraphs, will now be described with reference to FIG. 12. In a communication system 1200, a host computer 1210 comprises hardware 1215 including a communication interface 1216 configured to set up and maintain a wired or wireless connection with an interface of a different communication device of the communication system 1200. The host computer 1210 further comprises processing circuitry 1218, which may have storage and/or processing capabilities. In particular, the processing circuitry 1218 may comprise one or more programmable processors, application-specific integrated circuits, field programmable gate arrays or combinations of these (not shown) adapted to execute instructions. The host computer 1210 further comprises software 1211, which is stored in or accessible by the host computer 1210 and executable by the processing circuitry 1218. The software 1211 includes a host application 1212. The host application 1212 may be operable to provide a service to a remote user, such as a UE 1230 connecting via an OTT connection 1250 terminating at the UE 1230 and the host computer 1210. In providing the service to the remote user, the host application 1212 may provide user data, which is transmitted using the OTT connection 1250. The user data may depend on the location of the UE 1230. The user data may comprise auxiliary information or precision advertisements (also: ads) delivered to the UE 1230. Alternatively or in addition, the OTT connection 1250 may carry neuromorphic data and/or the user data may comprise neuromorphic data. The neuromorphic data may comprise data from a neuromorphic service, e.g., neuromorphic implementation of artificial intelligence (AI, or AI application). The location may be reported by the UE 1230 to the host computer, e.g., using the OTT connection 1250, and/or by the base station 1220, e.g., using a connection 1260.

The communication system 1200 further includes a base station 1220 provided in a telecommunication system and comprising hardware 1225 enabling it to communicate with the host computer 1210 and with the UE 1230. The hardware 1225 may include a communication interface 1226 for setting up and maintaining a wired or wireless connection with an interface of a different communication device of the communication system 1200, as well as a radio interface 1227 for setting up and maintaining at least a wireless connection 1270 with a UE 1230 located in a coverage area (not shown in FIG. 12) served by the base station 1220. The communication interface 1226 may be configured to facilitate a connection 1260 to the host computer 1210. The connection 1260 may be direct, or it may pass through a core network (not shown in FIG. 12) of the telecommunication system and/or through one or more intermediate networks outside the telecommunication system. In the embodiment shown, the hardware 1225 of the base station 1220 further includes processing circuitry 1228, which may comprise one or more programmable processors, application-specific integrated circuits, field programmable gate arrays or combinations of these (not shown) adapted to execute instructions. The base station 1220 further has software 1221 stored internally or accessible via an external connection.

The communication system 1200 further includes the UE 1230 already referred to. Its hardware 1235 may include a radio interface 1237 configured to set up and maintain a wireless connection 1270 with a base station serving a coverage area in which the UE 1230 is currently located. The hardware 1235 of the UE 1230 further includes processing circuitry 1238, which may comprise one or more programmable processors, application-specific integrated circuits, field programmable gate arrays or combinations of these (not shown) adapted to execute instructions. The UE 1230 further comprises software 1231, which is stored in or accessible by the UE 1230 and executable by the processing circuitry 1238. The software 1231 includes a client application 1232. The client application 1232 may be operable to provide a service to a human or non-human user via the UE 1230, with the support of the host computer 1210. In the host computer 1210, an executing host application 1212 may communicate with the executing client application 1232 via the OTT connection 1250 terminating at the UE 1230 and the host computer 1210. In providing the service to the user, the client application 1232 may receive request data from the host application 1212 and provide user data in response to the request data. The OTT connection 1250 may transfer both the request data and the user data. The client application 1232 may interact with the user to generate the user data that it provides.

It is noted that the host computer 1210, base station 1220 and UE 1230 illustrated in FIG. 12 may be identical to the host computer 1130, one of the base stations 1112a, 1112b, 1112c and one of the UEs 1191, 1192 of FIG. 11, respectively. This is to say, the inner workings of these entities may be as shown in FIG. 12, and, independently, the surrounding network topology may be that of FIG. 11.

In FIG. 12, the OTT connection 1250 has been drawn abstractly to illustrate the communication between the host computer 1210 and the UE 1230 via the base station 1220, without explicit reference to any intermediary devices and the precise routing of messages via these devices. Network infrastructure may determine the routing, which it may be configured to hide from the UE 1230 or from the service provider operating the host computer 1210, or both. While the OTT connection 1250 is active, the network infrastructure may further take decisions by which it dynamically changes the routing (e.g., on the basis of load balancing consideration or reconfiguration of the network).

The wireless connection 1270 between the UE 1230 and the base station 1220 is in accordance with the teachings of the embodiments described throughout this disclosure. One or more of the various embodiments improve the performance of OTT services provided to the UE 1230 using the OTT connection 1250, in which the wireless connection 1270 forms the last segment. More precisely, the teachings of these embodiments may reduce the latency and improve the data rate and thereby provide benefits such as better responsiveness and improved QoS.

A measurement procedure may be provided for the purpose of monitoring data rate, latency, QoS and other factors on which the one or more embodiments improve. There may further be an optional network functionality for reconfiguring the OTT connection 1250 between the host computer 1210 and UE 1230, in response to variations in the measurement results. The measurement procedure and/or the network functionality for reconfiguring the OTT connection 1250 may be implemented in the software 1211 of the host computer 1210 or in the software 1231 of the UE 1230, or both. In embodiments, sensors (not shown) may be deployed in or in association with communication devices through which the OTT connection 1250 passes; the sensors may participate in the measurement procedure by supplying values of the monitored quantities exemplified above, or supplying values of other physical quantities from which software 1211, 1231 may compute or estimate the monitored quantities. The reconfiguring of the OTT connection 1250 may include message format, retransmission settings, preferred routing etc.; the reconfiguring need not affect the base station 1220, and it may be unknown or imperceptible to the base station 1220. Such procedures and functionalities may be known and practiced in the art. In certain embodiments, measurements may involve proprietary UE signaling facilitating the host computer's 1210 measurements of throughput, propagation times, latency and the like. The measurements may be implemented in that the software 1211, 1231 causes messages to be transmitted, in particular empty or “dummy” messages, using the OTT connection 1250 while it monitors propagation times, errors etc.

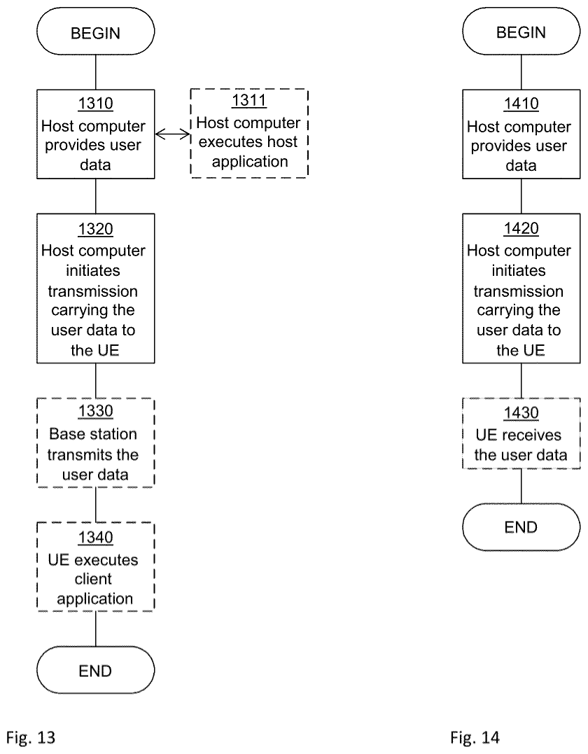

FIG. 13 is a flowchart illustrating a method implemented in a communication system, in accordance with one embodiment. The communication system includes a host computer, a base station and a UE which may be those described with reference to FIGS. 11 and 12. For simplicity of the present disclosure, only drawing references to FIG. 13 will be included in this paragraph. In a first step 1310 of the method, the host computer provides user data. In an optional substep 1311 of the first step 1310, the host computer provides the user data by executing a host application. In a second step 1320, the host computer initiates a transmission carrying the user data to the UE. In an optional third step 1330, the base station transmits to the UE the user data which was carried in the transmission that the host computer initiated, in accordance with the teachings of the embodiments described throughout this disclosure. In an optional fourth step 1340, the UE executes a client application associated with the host application executed by the host computer.

FIG. 14 is a flowchart illustrating a method implemented in a communication system, in accordance with one embodiment. The communication system includes a host computer, a base station and a UE which may be those described with reference to FIGS. 11 and 12. For simplicity of the present disclosure, only drawing references to FIG. 14 will be included in this paragraph. In a first step 1410 of the method, the host computer provides user data. In an optional substep (not shown) the host computer provides the user data by executing a host application. In a second step 1420, the host computer initiates a transmission carrying the user data to the UE. The transmission may pass via the base station, in accordance with the teachings of the embodiments described throughout this disclosure. In an optional third step 1430, the UE receives the user data carried in the transmission.

As has become apparent from above description, at least some embodiments of the technique can be directly mapped to existing, general purpose neuromorphic hardware and to available neuron models. Some embodiments do not require special purpose components. For example, there is no need for components that scale and transcode the analogue input signals.

Same or further embodiments supports spike-based input (e.g., as opposed to analogue-based encoding) for which DFT is to be computed. Thereby, it can be naturally integrated into a neuromorphic implemented application, there is no need to transcode from spiking domain to analogue signal.

In same or further embodiments, the input needs not (e.g., the binary-valued frequency domain components need not) to be synchronized (e.g., spikes corresponding to different frequency domain components may arrive asynchronously). Alternatively or in addition, the computation in the device 100 may be fully event driven. The computation may start when the event arrives.

Same or further embodiments can store the result in the neuron states of the output neuron, e.g., in the membrane potential as local memory of the output neurons. This contrasts with memristor-based solutions, wherein the input has to be given synchronously and the output has to be read out synchronously as well. The output may correspond to inner (e.g., membrane) potential of the output neurons.

Same or further embodiments allow a highly energy efficient implementation of the DFT computation and/or can be directly applied e.g., in low-power or zero-energy IoT transceiver devices for signal processing operations. Alternatively or in addition, it is possible to build a radio transceiver based completely on neuromorphic hardware, e.g., that does not include conventional central processing unit (CPU) or digital signal processor (DSP) or graphics processing unit (GPU) and memory elements.

Many advantages of the present invention will be fully understood from the foregoing description, and it will be apparent that various changes may be made in the form, construction and arrangement of the units and devices without departing from the scope of the invention and/or without sacrificing all of its advantages. Since the invention can be varied in many ways, it will be recognized that the invention should be limited only by the scope of the following claims.

1. A device for generating a time domain signal based on binary-valued frequency domain components, the device comprising:
input neurons representing binary values of the binary-valued frequency domain components;
neuromorphic couplings configured to map the binary-valued frequency domain components to time domain components of the time domain signal using weights according to an inverse discrete Fourier transformation, IDFT; and
output neurons representing the time domain components of the time domain signal, each of the output neurons being configured to sum up contributions mapped to the respective one of the output neurons by the neuromorphic couplings from each of the input neurons.

2. The device of claim 1, wherein the neuromorphic couplings comprise resistances corresponding to the weights, and wherein the contributions correspond to voltage drops at the resistances when currents corresponding to the binary-valued frequency domain components energize a respective one of the resistances.

3. The device of claim 1, wherein one or both:
a spike input at any one of the input neurons corresponds to a value of one of the respective one of the binary-valued frequency domain components; and
the absence of a spike input at any one of the input neurons within a predefined time window corresponds to a value of zero of the respective one of the binary-valued frequency domain components.

4. The device of claim 1, wherein one or both:
the neuromorphic couplings are configured to energize a respective one of the weights for the mapping only when the binary-valued frequency domain component, which is mapped using the respective one of the weights, comprises a value of one; and
the neuromorphic couplings are configured to not energize a respective one of the weights for the mapping when the binary-valued frequency domain component, which is mapped using the respective one of the weights, comprises a value of zero.

5. The device of claim 1, wherein at least one or each of the output neurons comprises a spiking threshold, and wherein the spiking threshold of the respective one of the output neurons is greater than the highest possible inner potential of the respective one of the output neurons that is reachable by activations on the input neurons.

6. The device of claim 1, wherein the input neurons are configured to receive a spike signal representing application data encoded into spike activations.

7. The device of claim 1, wherein one or both:
at least one or each of the output neurons comprises an electric potential representing a respective one of the time domain components; and
at least one or each of the output neurons is configured to aggregate spike signals in the contributions resulting from the neuromorphic couplings mapping spike signals in the binary-valued frequency domain components from the input neurons.

8. The device of claim 1, wherein the input neurons comprise a first input set of input neurons and a second input set of input neurons that is disjoint from the first input set, wherein the first input set is mapped to the time domain components using the weights according to the IDFT and the second input set is mapped to the time domain components using the weights according to the IDFT with inverted sign.

9. The device of claim 1, wherein the input neurons comprise a first input set of input neurons and a second input set of input neurons that is disjoint from the first input set, wherein the first input set is mapped to the time domain components using the weights according to the IDFT and the second input set is mapped to the time domain components using the weights according to the IDFT, wherein each of the output neurons is configured to sum up contributions mapped to the respective one of the output neurons from the first input set, and each of the output neurons is configured to subtract contributions mapped to the respective one of the output neurons from the second input set.

10. The device of claim 8, wherein corresponding pairs of input neurons in the first and second sets represent a modulation symbol according to at least one of on-off-keying, OOK, and phase-shift keying, PSK.

11. The device of claim 1, wherein the input neurons comprise mutually disjoint first, second, third, and fourth input sets of input neurons, wherein the first input set is mapped to the time domain components using the weights according to the IDFT, the second input set is mapped to the time domain components using the weights according to the IDFT with inverted sign, the third input set is mapped to the time domain components using the weights according to the IDFT with a phase shift by +90 degrees, and the fourth input set is mapped to the time domain components using the weights according to the IDFT with a phase shift by degrees.

12. The device of claim 11, wherein corresponding groups of input neurons in the first, second, third, and fourth sets represent a modulation symbol according to at least one of Quadrature Phase-Shift Keying, QPSK, and Quadrature Amplitude Modulation, QAM, 4.

13. The device of claim 1, wherein the output neurons comprise a first output set of output neurons and a second output set of output neurons that is disjoint from the first output set, wherein the neuromorphic couplings are configured to map the binary-valued frequency domain components to the first output set using weights according to the real part of the IDFT, and wherein the neuromorphic couplings are configured to further map the binary-valued frequency domain components to the second output set using weights according to the imaginary part of the IDFT.

14. The device of claim 1, wherein the input neurons comprise an odd input set of N input neurons corresponding to odd frequency domain components and an even input set of N input neurons corresponding to even frequency domain components, wherein each of the odd input set and the even input set is mapped to the time domain components using the weights according to the IDFT of size N, wherein the neuromorphic couplings or the output neurons are configured to sum up the contributions mapped to the respective one of the output neurons from the odd input set and the contributions mapped to the respective one of the output neurons from the even input set for the first N output neurons, and wherein the neuromorphic couplings or the output neurons are configured to subtract the contributions mapped to the respective one of the output neurons from the even input set from the contributions mapped to the respective one of the output neurons from the odd input set for the second N output neurons.

15. The device of claim 1, wherein one or both of at least one or each of the input neurons and at least one or each of the output neurons comprises a reactance, a capacitance or an inductance, for asynchronously collecting one or more spikes representing the binary value of the binary-valued frequency domain components.

16. The device of claim 1,
further comprising a demultiplexing unit, the demultiplexing unit comprising a clock and a cyclic counter, wherein the clock is configured to cyclically increase the cyclic counter, and wherein the time domain components are read out from the output neurons according to the cyclic counter.

17. The device of claim 1, further comprising a radio frequency converter configured to up-converting a real part of a current one of the time domain components to a radio frequency and to up-converting an imaginary part of a current one of the time domain components to the radio frequency with a 90 degree phase shift.

18. (canceled)

19. A user equipment, UE, configured to communicate with a base station on an uplink, UL, or with another radio device on a sidelink, SL, the UE comprising:
a radio interface for transmitting an OFDM symbol;
a device for neuromorphic computation; and
a processing circuitry coupled to memory that is configured to store instructions of a radio communications protocol, the processing circuitry is being operable to execute the instructions such that the processing circuitry provides the binary-valued frequency domain components to the input neurons of the device, the output neurons of the device being coupled to the radio interface to provide the time domain signal comprising the OFDM symbol.

20. A method of generating a time domain signal based on binary-valued frequency domain components, the method comprising:
representing binary values of the binary-valued frequency domain components in input neurons;
mapping the binary-valued frequency domain components to time domain components of the time domain signal using weights according to an inverse discrete Fourier transformation, IDFT, in neuromorphic couplings; and
representing the time domain components of the time domain signal in output neurons, each of the output neurons being configured to sum up contributions mapped to the respective one of the output neurons by the neuromorphic couplings from each of the input neurons.

21. The method of claim 20, wherein the neuromorphic couplings comprise resistances corresponding to the weights, and wherein the contributions correspond to voltage drops at the resistances when currents corresponding to the binary-valued frequency domain components energize a respective one of the resistances.

22.-25. (canceled)
